(19) United States
(12) Patent Application Publication
(10) Pub. No.: US 2010/0037952 A1
(43) Pub. Date: Feb. 18, 2010

(54) Selective Emitter Solar Cell and Fabrication Method Thereof

(75) Inventor: Jang-Shen Lin, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 12/541,945

(22) Filed: Aug. 15, 2009

(30) Foreign Application Priority Data
Aug. 18, 2008 (CN) 200810041831.8

(51) Int. Cl. H01L 31/00; H01L 31/0232; H01L 21/50

(52) U.S. Cl. 136/256; 438/65; 257/E31.127; 257/E21.499

(57) ABSTRACT

A fabrication method of a selective emitter solar cell, including: forming a selective emitter solar cell base having a buried grid electrode; forming an anti-reflection layer on the emitter surface of the solar cell base; forming a bus-bar on the anti-reflection layer; and connecting the buried grid electrode with the bus-bar in the traversing direction underneath through the anti-reflection layer. Accordingly, the invention provides a selective emitter solar cell. With the method of the invention, emitters and bus-bars are made separately, the width of the emitters can be reduced according to actual needs, the area that is unnecessarily taken may be reduced, the effective area for a solar cell panel to receive sunlight may be increased. The invention improves conversion efficiency of a selective emitter solar cell panel from 16.5% to 18% or more.

### FIELD OF THE INVENTION

The present invention relates to the field of semiconductor manufacture, and in particular to a selective emitter solar cell and a fabrication method thereof.

### BACKGROUND OF THE INVENTION

Due to limitations of conventional energy supplies and an increasing pressure to environmental protection, there is a trend of developing and using new energies in many countries. Among those new energies, the solar energy, as a clean, non-polluting and inexhaustible green energy, has drawn great attention and been heavily researched in most of the countries. In the world where energy deficiency is increasingly severe, the solar energy has a broad future.

Using solar cells to convert solar energy into electrical energy is an important technical basis for massive utilization of solar energy. The ratio between the part of solar energy converted into electrical energy and the solar energy received by a solar cell, named conversion efficiency, is up to 29% theoretically. Nowadays, with a series of complex and expensive processes in laboratories, the conversion efficiency may reach about 24%. However, the conversion efficiency is lower in industry, usually less than 20%. Many efforts have been made to improve the conversion efficiency of solar cells, e.g. the solar cell with a selective emitter structure has been fabricated.

More information regarding the selective emitter solar cell structure can be found in the paper “Selective Emitter Solar Cell Structure and Implementation Method thereof” (Qu Sheng, Liu Zuming, Liao Hua and Chen Tingquan, Solar Energy Research Institute of Yunnan Normal University) published on Chinese journal “Information of China Construction: Solar Energy” (ISSN 1008-570X): 42-45 (August, 2004).

FIG. 1 illustrates a conventional method for fabrication of a selective emitter solar cell. A lightly-doped shallow diffusion region 102 is formed on a semiconductor substrate 100. Different-sized heavily-doped deep diffused grooves 106 and 110 are formed in the semiconductor substrate 100. Metal materials 104 and 108 are formed in the heavily-doped deep diffused grooves 106 and 110 to be used as an emitter or a bus-bar. The thin metal material 108 is used as an emitter to collect electric currents produced by photon generated charge carriers at the P-N junction. The thick metal material 104 functions not only as an emitter collecting electric currents produced by photon generated charge carriers at the P-N junction, but also as a bus-bar through which the solar cell outputs electric currents. Therefore, in fabrication of the solar cell, some thick electrodes 104 have to be made selectively, which may take up the area for the solar cell panel, decrease the effective area for the solar cell panel to receive sunlight, and increase the contact resistance between the thick electrode 104 and the heavily-doped deep diffused groove 106. Moreover, in the conventional art, the doping concentration of the semiconductor substrate surface is high, which may lower the ability for a solar cell to collect photon generated charge carriers, especially shortwave photon generated charge carriers. All of the above may cause a lower conversion efficiency of a solar cell.

### SUMMARY OF THE INVENTION

A problem to be solved by the invention is to provide a selective emitter solar cell and a fabrication method thereof to improve the conversion efficiency of the solar cell.

To solve the problem, the invention provides a fabrication method of a selective emitter solar cell, including: forming a selective emitter solar cell base having a buried grid electrode; forming an anti-reflection layer on the emitter surface of the solar cell base; forming a bus-bar on the anti-reflection layer; connecting the bus-bar with the buried grid electrode in the traversing direction underneath through the anti-reflection layer.

Optionally, the forming of the selective emitter solar cell base having a buried grid electrode includes: forming an emitter groove in a semiconductor substrate; forming an emitter P-N junction near the emitter groove in the semiconductor substrate; and forming a barrier layer, a conducting layer and a bond layer sequentially in the emitter groove, which form the buried grid electrode.

Optionally, the emitter groove has a width of 10-50 82 m and a depth of 10-50 μm.

Optionally, the bus-bar has a width of 3000-5000 μm.

Optionally, the semiconductor substrate surface has a sheet resistance larger than 100 Ω/□.

Optionally, the emitter groove surface has a sheet resistance less than 30 Ω/□.

Optionally, the material of the barrier layer is nickel, the material of the conducting layer is copper, and the material of the bond layer is silver.

Optionally, the barrier layer has a thickness of 2˜20 μm, the conducting layer has a thickness of 5˜50 μm, the bond layer has a thickness of 5˜50 μm.

Optionally, the material of the bus-bar is silver.

Optionally, the bus-bar and the buried grid electrode are arranged perpendicularly to each other.

Optionally, the buried grid electrodes are arranged in parallel to each other with the same distance therebetween.

Optionally, the bus-bars are arranged in parallel to each other with the same distance therebetween.

Optionally, the forming of a selective emitter solar cell base includes forming a sub-buried grid electrode.

Optionally, the sub-buried grid electrode and the buried grid electrode intersect perpendicularly in the same plane, and the sub-buried grid electrode lies right underneath the bus-bar and in parallel to the bus-bar.

Optionally, the solar cell base is co-fired. The bus-bar is connected with the buried grid electrode in the traversing direction underneath through the anti-reflection layer.

The invention also provides a selective emitter solar cell, including: a selective emitter solar cell base having a buried grid electrode; an anti-reflection layer formed on the emitter surface of the solar cell base; and a bus-bar formed on the anti-reflection layer, which is connected with the buried grid electrode in the traversing direction underneath through the anti-reflection layer.

Optionally, the selective emitter solar cell base having a buried grid electrode includes: a semiconductor substrate; an emitter groove formed in the semiconductor substrate; an emitter P-N junction formed near the emitter groove in the semiconductor substrate; and a barrier layer, a conducting layer and a bond layer formed sequentially in the emitter groove.

Optionally, the emitter groove has a width of 10˜50 μm and a depth of 10˜50 μm.

Optionally, the bus-bar has a width of 3000˜5000 μm.

Optionally, the semiconductor substrate surface has a sheet resistance larger than 100 Ω/□.

Optionally, the emitter groove surface has a sheet resistance less than 30 Ω/□.

Optionally, the material of the barrier layer is nickel, the material of the conducting layer is copper, and the material of the bond layer is silver.

Optionally, the barrier layer has a thickness of 2˜20 μm, the conducting layer has a thickness of 5˜50 μm, the bond layer has a thickness of 5˜50 μm.

Optionally, the material of the bus-bar is silver.

Optionally, the bus-bar and the buried grid electrode are arranged perpendicularly to each other.

Optionally, the buried grid electrodes are arranged in parallel to each other with the same distance therebetween.

Optionally, the bus-bars are arranged in parallel to each other with the same distance therebetween.

Optionally, in forming of the selective emitter solar cell base, a sub-buried grid electrode is formed.

Optionally, the sub-buried grid electrode and the buried grid electrode intersect perpendicularly in the same plane, and the sub-buried grid electrode lies right underneath the bus-bar and in parallel to the bus-bar.

Compared with the conventional art, the present invention may bring the following advantages: in the method for fabricating a selective emitter solar cell, an anti-reflection layer is formed on a surface of a selective emitter solar cell base; the selective emitter solar cell base has buried grid electrodes; bus-bars are formed on the anti-reflection layer, and are connected with the buried grid electrodes used as emitters in the traversing direction underneath through the anti-reflection layer. Therefore, the emitters and the bus-bars can be made separately, the width of the emitters can be reduced according to actual needs, the area that is unnecessarily taken may be reduced, the effective area for a solar cell panel to receive sunlight may be increased, the contact resistance between the emitters and emitter grooves may be reduced, which may lead to an improved conversion efficiency of the solar cell panel.

In addition, in the method for fabricating a selective emitter solar cell, a lowered doping concentration of the semiconductor substrate surface may improve the ability for the solar cell to collect photon generated charge carriers, especially shortwave photon generated charge carriers.

Furthermore, in the method for fabricating a selective emitter solar cell, the buried grid electrode and the bus-bar are arranged perpendicularly to each other. This may avoid position offsets due to a parallel arrangement between the buried grid electrode and the bus-bar, and thus avoid the resulting poor contact therebetween.

Finally, in the method for fabricating a selective emitter solar cell, some sub-buried grid electrodes, which intersect perpendicularly with the buried grid electrodes in the same plane, are made when the buried grid electrodes are made, and, the sub-buried grid electrodes lie right underneath and in parallel to the subsequent bus-bars. Therefore, the contact area between the buried grid electrodes and the bus-bars may be increased, and the contact resistance therebetween may be reduced.

Due to the technical improvements as mentioned above, the conversion efficiency of a selective emitter solar cell panel made based on the present invention is increased from 16.5% to 18% or more.

### BRIEF DESCRIPTION OF THE DRAWINGS

FIG. 1 illustrates a sectional view of a selective emitter solar cell according to the conventional art;

FIG. 2 illustrates a flow chart of a method for fabricating a selective emitter solar cell according to an embodiment of the invention;

FIG. 3 illustrates a top-view of a selective emitter solar cell according to an embodiment of the invention;

FIG. 4 to FIG. 9 illustrate sectional views of a selective emitter solar cell according to an embodiment of the invention;

FIG. 10 illustrates a top-view of a selective emitter solar cell base having buried grid electrodes according to another embodiment of the invention; and

FIG. 11 to FIG. 14 illustrate sectional views of a selective emitter solar cell base according to an embodiment of the invention.

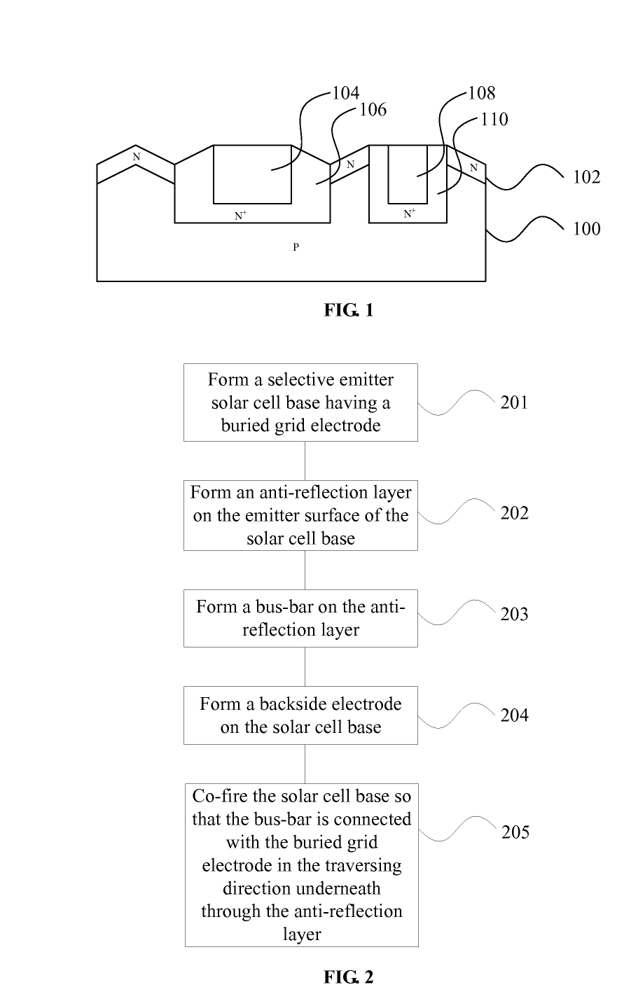

### DETAILED DESCRIPTION OF THE INVENTION

In the method for fabricating a selective emitter solar cell according to the invention, an anti-reflection layer is formed on a surface of a selective emitter solar cell base. The selective emitter solar cell base has buried grid electrodes. Bus-bars are formed on the anti-reflection layer. The Bus-bars are connected with the buried grid electrodes used as emitters in the traversing direction underneath through the anti-reflection layer. Therefore, the emitters and the bus-bars can be made separately. The width of the emitters can be reduced according to actual needs, the area that is unnecessarily taken may be reduced, the effective area for a solar cell panel to receive sunlight may be increased, the contact resistance between the emitters and emitter grooves may be reduced, which may lead to an improved conversion efficiency of the solar cell panel.

In addition, in the method for fabricating a selective emitter solar cell, a lowered doping concentration of the semiconductor substrate surface may improve the ability for the solar cell to collect photon generated charge carriers, especially shortwave photon generated charge carriers.

Furthermore, in the method for fabricating a selective emitter solar cell, the buried grid electrode and the bus-bar are arranged perpendicularly to each other. This may avoid position offsets due to a parallel arrangement between the buried grid electrode and the bus-bar, and thus avoid the resulting poor contact therebetween.

Finally, in the method for fabricating a selective emitter solar cell, some sub-buried grid electrodes, which intersect perpendicularly with the buried grid electrodes in the same plane, are made when the buried grid electrodes are made. Furthermore, the sub-buried grid electrodes lie right underneath and in parallel to the subsequent bus-bars. Therefore, the contact area between the buried grid electrodes and the bus-bars may be increased, and the contact resistance therebetween may be reduced.

Due to the technical improvements as mentioned above, the conversion efficiency of a selective emitter solar cell panel made based on the present invention is increased from 16.5% to 18% or more.

The invention will be described hereinafter in conjunction with embodiments and the drawings, which should not be treated as limitations of the scope of the invention.

FIG. 2 is a flow chart of a method for forming a selective emitter solar cell according to an embodiment of the invention. As illustrated in FIG. 2, the method includes: step S201, forming a selective emitter solar cell base having a buried grid electrode; step S202, forming an anti-reflection layer on the emitter surface of the solar cell base; step 203, forming bus-bars on the anti-reflection layer; step 204, forming a backside electrode on the solar cell base; and step S205, co-firing the solar cell base, so that the bus-bar is connected with the buried grid electrode in the traversing direction underneath through the anti-reflection layer.

In this embodiment, the buried grid electrodes refer to emitters that are buried in the semiconductor substrate, and the co-firing is a heat treatment process in which two or more types of materials are heated together.

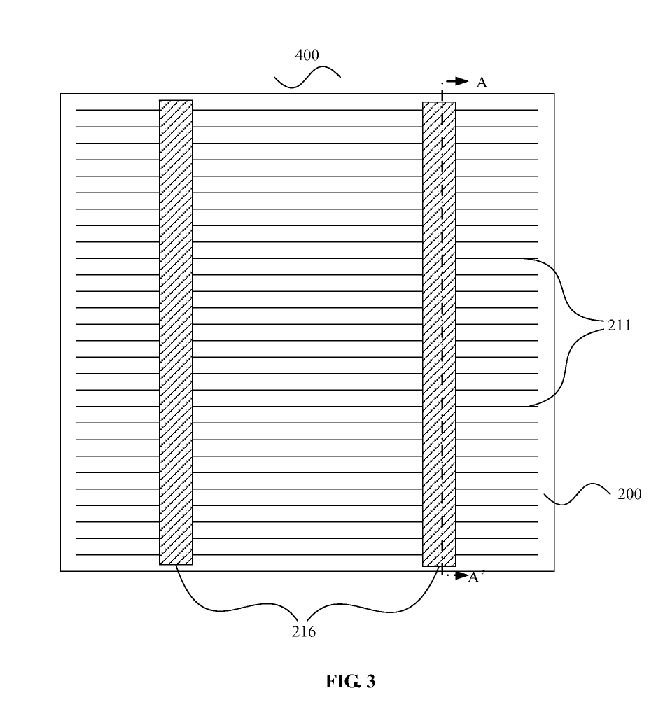

FIG. 3 is a top-view of a selective emitter solar cell according to an embodiment of the invention. The selective emitter solar cell 400 includes a semiconductor substrate 200, buried grid electrodes 211 which are buried in the semiconductor substrate 200 as emitters of the solar cell, and bus-bars 216 which lie above the semiconductor substrate 200 and buried grid electrodes 211 and are perpendicular to the buried grid electrodes 211. The bus-bars 216 are connected with the buried grid electrodes 211 in the traversing direction underneath through an anti-reflection layer (not shown in the figure) that covers the semiconductor substrate 200 and the buried grid electrodes 211.

In other embodiments, the bus-bars 216 and the buried grid electrodes 211 underneath may be arranged obliquely to each other, and the bus-bars may even have various shapes, e.g. the shape of an arc, or a spiral shape.

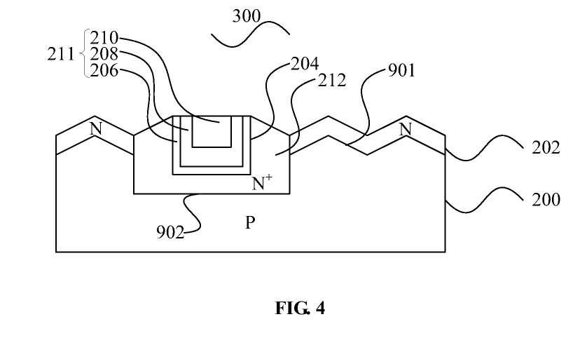

FIG. 4 to FIG. 9 are sectional views of a selective emitter solar cell according to an embodiment of the invention, with a cutting plane line A-A′ in FIG. 3.

As illustrated in FIG. 4, a selective emitter solar cell base 300 having buried grid electrodes is provided. The solar cell base 300 includes: a P-type semiconductor substrate 200, the surface 202 of which is N-type and has a certain depth, accordingly a surface P-N junction 901 is formed near the surface of the semiconductor substrate 200; an emitter groove 204 formed in the semiconductor substrate 200, which has a depth greater than that of the surface P-N junction 901; an emitter P-N junction 902 formed near the emitter groove in the semiconductor substrate 204, the doping impurity is N-type, and the doping concentration of the region 212 near the emitter groove 204 is higher than that of the surface 202 of the semiconductor substrate 200; a buried grid electrode 211 formed in the emitter groove 204, which is used as an emitter of the solar cell and includes a barrier layer 206, a conducting layer 208 and a bond layer 210 that are formed sequentially.

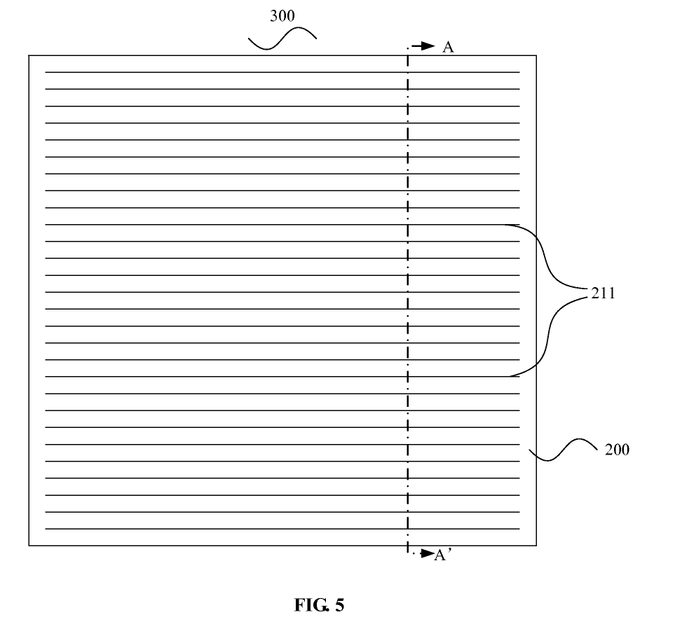

In this embodiment, a top view of the selective emitter solar cell base 300 having buried grid electrodes is as illustrated in FIG. 5. The buried grid electrodes 211 that are buried in the semiconductor substrate 200 as emitters of the solar cell are arranged in parallel to each other with the same distance therebetween.

In other embodiments, the distances between the buried grid electrodes 211 may also be different.

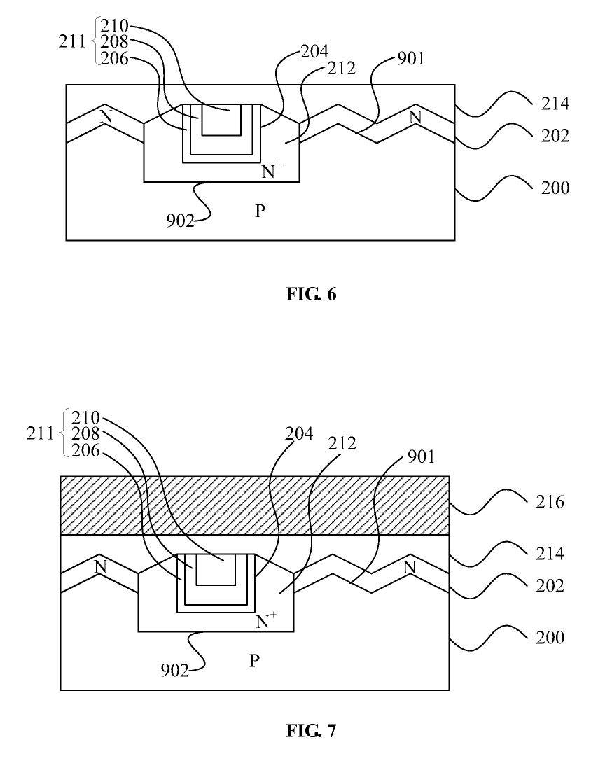

As shown in FIG. 6, an anti-reflection layer 214 is formed on the emitter surface of the selective emitter solar cell base 300. The anti-reflection layer 214 may be formed using a method known in the art, e.g. chemical vapor deposition. The material of the anti-reflection layer 214 may be silicon nitride, silicon oxide or a combination of them, in order to reduce total reflection and diffuse reflection resulting from a smooth solar cell panel surface in receiving sunlight.

As shown in FIG. 7, a bus-bar 216 is formed on the anti-reflection layer 214. The bus-bar 216 may be formed using a method known in the art, e.g. screen printing. The width of the bus-bar may be 3000˜5000 μm, and the material of the bus-bar may be silver. The bus-bars may be arranged in parallel to each other with the same distance therebetween, the bus-bar and the buried grid electrode may be arranged perpendicularly to each other. The bus-bars 216 is be used to collect electric currents produced by photon generated charge carriers at each buried grid electrode 211, and as an interface for the selective emitter solar cell panel to output electric currents.

In various embodiments, the width of the bus-bar 216 may be determined according to actual needs, e.g. 3000 μm, 3500 μm, 4000 μm, 4500 μm or 5000 μm, preferably, 4000 μm.

In other embodiments, the distances between the bus-bars 216 may also be different.

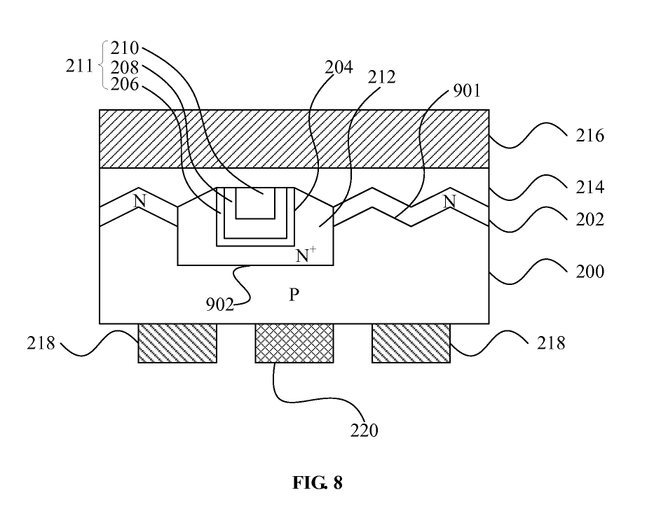

As shown in FIG. 8, a backside electrode 220 is formed on the selective emitter solar cell base 300. The backside electrode 220 may be formed using a method known in the art, e.g. screen printing. The backside electrode 220 may be formed with a Back Side Field (BSF) 218; the material of the backside electrode 220 may be silver, the material of the BSF 218 may be aluminum. The backside electrode 220 and the bus-bars 216 of the solar cell base 300 form a circuit loop as an interface for the selective emitter solar cell panel to output electric currents. The BSF 218 may be used to increase the collection efficiency of minority carriers, and may also be used as an impurity absorber for the semiconductor substrate 200.

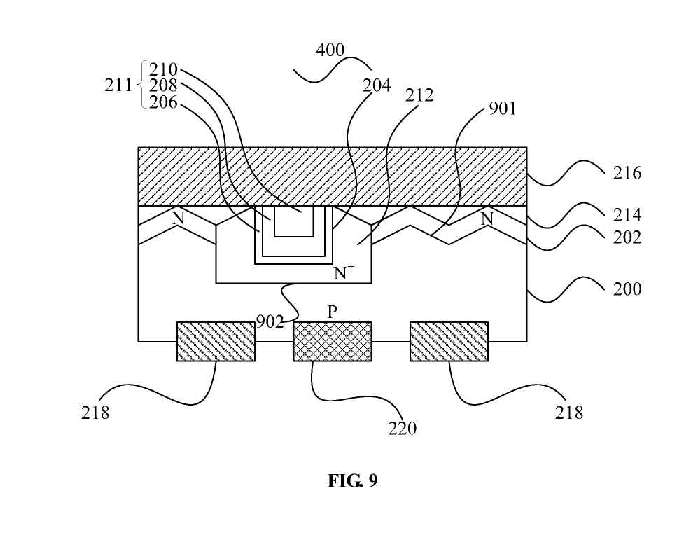

As shown in FIG. 9, the selective emitter solar cell base 300 is co-fired, so that the bus-bar 216 is connected with the buried grid electrode 211 in the traversing direction underneath through the anti-reflection layer 214, meanwhile the backside electrode 220 and the BSF 218 partially permeate into the semiconductor substrate 200 under the high temperature, therefore the final selective emitter solar cell 400 is formed.

In other embodiments, different methods can be used to implement the connection between the bus-bars with the buried grid electrodes. For example, some grooves may be formed on the anti-reflection layer 214, in which metal material is filled to form bus-bars 216, thereby the bus-bars 216 is connected with the buried grid electrodes 211 in the traversing direction underneath through the anti-reflection layer 214.

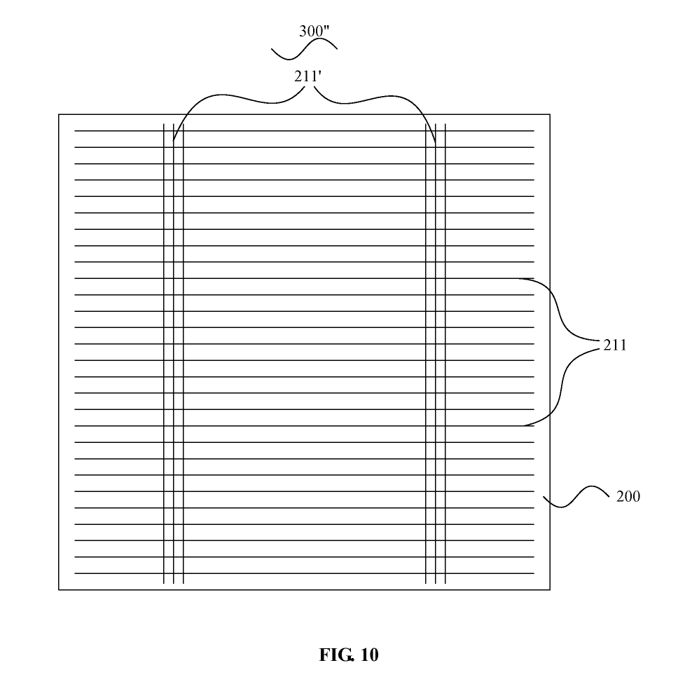

FIG. 10 illustrates a top-view of a selective emitter solar cell base 300 having buried grid electrodes according to another embodiment of the invention. The selective emitter solar cell base 300 includes buried grid electrodes 211 and sub-buried grid electrodes 211′. The sub-buried grid electrode 211′ intersects with the buried grid electrode 211 in the same plane, and the sub-buried grid electrode lies right underneath the subsequent bus-bar 216 (not shown) and in parallel to the bus-bar 216. The fabrication method and material of the sub-buried grid electrodes 211′ is the same as the buried grid electrodes 211. The width and the depth of the sub-buried grid electrodes 211′ may be determined according to actual needs. The sub-buried grid electrode 211′ may increase the contact area between the bus-bar and the buried grid electrode 211 underneath, and reduce the contact resistance.

In the embodiment, in order to simplify the manufacture process and reduce the production procedure, the sub-buried grid electrodes 211′ have a width and a depth the same as the buried grid electrodes 211.

FIG. 11 to FIG. 14 illustrates sectional views of a selective emitter solar cell base according to an embodiment of the invention, with a cutting plane line A-A′ in FIG. 5.

As shown in FIG. 11, a semiconductor substrate 200 is provided. The semiconductor substrate 200 is P-type, with a textured surface 201. The textured surface 201 may be formed on the surface of the semiconductor substrate 200 using a method known in the art, e.g. etching the semiconductor substrate with acid solutions or alkaline solutions.

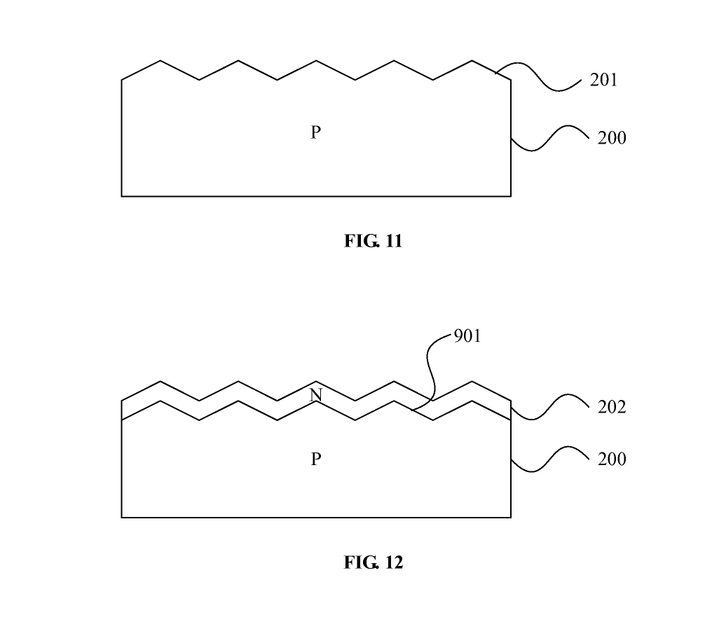

As shown in FIG. 12, the surface of the semiconductor substrate 200 is doped. The method of doping may be one of the methods known in the art, e.g. diffusion. The doping impurity may be phosphorus oxychloride (POCl₃).The doped surface of the semiconductor substrate is N-type, and extends into the semiconductor substrate 200. An N-type doped layer 202 with a certain depth is formed near the surface of the semiconductor substrate 200. The N-type doped layer 202 and the P-type semiconductor substrate 200 form a surface P-N junction 901.

In the embodiment, the sheet resistance of the semiconductor substrate surface 200 is greater than 100 Ω/□.

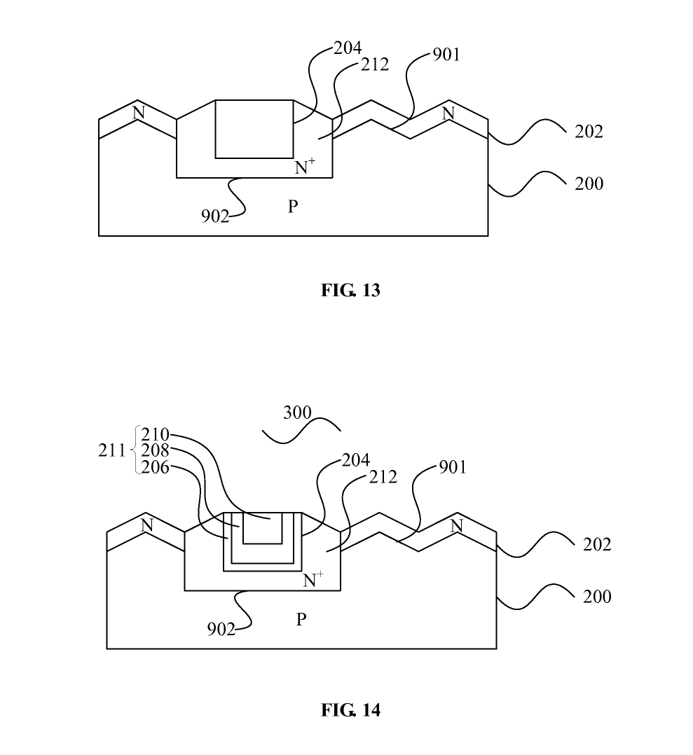

As shown in FIG. 13, an emitter groove 204 is formed in the semiconductor substrate 200, the depth of which is greater than that of the P-N junction 901. The emitter groove 204 is doped using one of the methods known in the art, e.g. diffusion. The doping impurity may be phosphorus oxychloride (POCl3). The doped surface of the emitter groove 204 is N-type, and extends into the semiconductor substrate 200. An N-type doped layer 212 with a certain thickness/depth is formed near the emitter groove 204. The doping concentration of the N-type doped layer 212 is larger than that of the N-type doped layer 202 formed near the semiconductor substrate 200. The N-type doped layer 212 and the P-type semiconductor substrate 200 form an emitter P-N junction 902. Then the semiconductor substrate 200 is cleaned in hydrofluoric acid in order to remove the insulating layer on the surface of the emitter groove 204 (not shown in the figure).

In the embodiment, the method for forming the emitter groove 204 in the semiconductor substrate 200 may be laser cutting or diamond saw cutting. The width of the emitter groove 204 formed may be 10˜50 μm, and the depth may be 10˜50 μm.

In other embodiments, the width of the emitter groove 204 formed may be e.g. 10 μm, 20 μm, 30 μm, 40 μm, or 50 μm, preferably 25 μm. The depth of the emitter groove 204 formed may be e.g. 10 μm, 20 μm, 30 μm, 40 μm or 50 μm, preferably 25 μm.

In the embodiment, the sheet resistance of the N-type doped emitter groove 204 surface is less than 30 Ω/□.

In the embodiment, the insulating layer on the surface of the emitter groove 204 is a dense silicon dioxide layer formed on the surface of the semiconductor substrate 200 including the surface of the emitter groove 204, due to the reaction between oxygen and the semiconductor substrate 200 made of silicon. The insulating layer is removed by hydrofluoric acid because it blocks the electric connection between the emitter P-N junction 902 and the subsequent emitter (not shown in the figure) and results in an open circuit.

As shown in FIG. 14, a barrier layer 206, a conducting layer 208 and a bond layer 210 are formed sequentially in the emitter groove 204, thereby forming a selective emitter solar cell base 300 having a buried grid electrode. The barrier layer 206, the conducting layer 208 and the bond layer 210 together constitute the buried grid electrode 211, which is used as an emitter of the selective emitter solar cell. The material of the barrier layer 206 may be nickel, the material of the conducting layer 208 may be copper, and the material of the bond layer 210 may be silver. The barrier layer 206, the conducting layer 208 and the bond layer 210 may be formed using a method known in the art, e.g. electroplating. The barrier layer 206 is used to block the subsequent conducting layer 208, thereby avoiding possible harmful spikes formed in the semiconductor substrate 200 if the conducting layer 208 goes through the surface of the emitter groove 204. The conducting layer 208 is used to connect the emitter P-N junction 902 and the subsequent bus-bar 216 (not shown in the figure), so as to output electronic currents collected on the solar cell panel through the bus-bar 216. The bond layer 210 is used to get a better connection between the emitter and the subsequent bus-bar 216.

In various embodiments, the thickness of the barrier layer 206 may be 2˜20 μm; the thickness of the conducting layer 208 may be 5˜50 μm; and the thickness of the bond layer 210 may be 5˜50 μm.

In various embodiments, the thickness of the barrier layer 206 may be e.g. 2 μm, 5 μm, 8 μm, 11 μm, 14 μm, 17 μm or 20 μm, preferably 8 μm. The thickness of the conducting layer 208 may be e.g. 5 μm, 15 μm, 25 μm, 35 μm, 45 μm or 50 μm, preferably 25 μm. The thickness of the bond layer 210 may be 5 μm, 15 μm, 25 μm, 35 μm, 45 μm or 50 μm, preferably 15 μm.

In the embodiment, the method for forming the selective emitter solar cell base 300 further comprises cutting peripheral P-N junction parts of the semiconductor substrate 200 (not shown in the figure), and cleaning the semiconductor substrate 200 in hydrofluoric acid to remove the insulating layer on the surface of the emitter substrate 200 (not shown in the figure).

In the embodiment, the insulating layer on the surface of the emitter groove 204 is a dense silicon dioxide layer formed on the surface of the semiconductor substrate 200, due to the reaction between oxygen and the semiconductor substrate 200 made of silicon. The insulating layer is removed with hydrofluoric acid because it blocks the electric connection between the buried grid electrode 211 and the subsequent bus-bar 216 (not shown in the figure), and blocks the electric connection between the subsequent backside electrode 220 and the BSF 218, thereby resulting in an open circuit.

In the method for fabricating a selective emitter solar cell according to the invention, an anti-reflection layer is formed on a surface of a selective emitter solar cell base; the selective emitter solar cell base has buried grid electrodes; bus-bars are formed on the anti-reflection layer, and are connected with the buried grid electrodes used as emitters in the traversing direction underneath through the anti-reflection layer. Therefore, the emitters and the bus-bars can be made separately, the width of the emitters can be reduced according to actual needs, the area that is unnecessarily taken may be reduced, the effective area for a solar cell panel to receive sunlight may be increased, the contact resistance between the emitters and emitter grooves may be reduced, which may lead to improved conversion efficiency of the solar cell panel.

In addition, in the method for fabricating a selective emitter solar cell, a lowered doping concentration of the semiconductor substrate surface may improve the ability for the solar cell to collect photon generated charge carriers, especially shortwave photon generated charge carriers.

Furthermore, in the method for fabricating a selective emitter solar cell, the buried grid electrode and the bus-bar are arranged perpendicularly to each other. This may avoid position offsets due to a parallel arrangement between the buried grid electrode and the bus-bar, and thus avoid the resulting poor contact therebetween.

Finally, in the method for fabricating a selective emitter solar cell, sub-buried grid electrodes which intersect perpendicularly with the buried grid electrodes in the same plane are made when the buried grid electrodes are made, and, the sub-buried grid electrodes lie right underneath and in parallel to the subsequent bus-bars. Therefore, the contact area between the buried grid electrodes and the bus-bars may be increased, and the contact resistance therebetween may be reduced.

Due to the technical improvements as mentioned above, the conversion efficiency of a selective emitter solar cell panel made based on the present invention is increased from 16.5% to 18% or more.

Preferred embodiments of the invention are described above, which is not intended to limit the invention. Various alternations and modifications can be made by those skilled in the art without departing from the scope of the invention, which is defined by the appended claims.

What is claimed is:

1. A method for fabricating a selective emitter solar cell, comprising:
forming a selective emitter solar cell base having a buried grid electrode;
forming an anti-reflection layer on the emitter surface of the solar cell base;
forming a bus-bar on the anti-reflection layer; and
connecting the bus-bar with the buried grid electrode in the traversing direction underneath through the anti-reflection layer.

2. The method for fabricating a selective emitter solar cell according to claim 1, wherein the forming of a selective emitter solar cell base having a buried grid electrode comprises:
forming an emitter groove in a semiconductor substrate;
forming an emitter P-N junction near the emitter groove in the semiconductor substrate; and
forming a barrier layer, a conducting layer and a bond layer sequentially in the emitter groove, which form the buried grid electrode.

3. The method for fabricating a selective emitter solar cell according to claim 2, wherein the emitter groove has a width of 10-50 μm and a depth of 10-50 μm.

4. The method for fabricating a selective emitter solar cell according to claim 1, wherein the bus-bar has a width of 3000-5000 μm.

5. The method for fabricating a selective emitter solar cell according to claim 2, wherein the semiconductor substrate surface has a sheet resistance larger than 100 Ω/□.

6. The method for fabricating a selective emitter solar cell according to claim 2, wherein the emitter groove surface has a sheet resistance less than 30 Ω/□.

7. The method for fabricating a selective emitter solar cell according to claim 2, wherein the material of the barrier layer is nickel, the material of the conducting layer is copper, and the material of the bond layer is silver.

8. The method for fabricating a selective emitter solar cell according to claim 2, wherein the barrier layer has a thickness of 2˜20 μm, the conducting layer has a thickness of 5˜50 μm, the bond layer has a thickness of 5˜50 μm.

9. The method for fabricating a selective emitter solar cell according to claim 1, wherein the material of the bus-bar is silver.

10. The method for fabricating a selective emitter solar cell according to claim 1, wherein the bus-bar and the buried grid electrode are arranged perpendicularly to each other.

11. The method for fabricating a selective emitter solar cell according to claim 10, wherein the buried grid electrodes are arranged in parallel to each other with the same distance therebetween.

12. The method for fabricating a selective emitter solar cell according to claim 10, wherein the bus-bars are arranged in parallel to each other with the same distance therebetween.

13. The method for fabricating a selective emitter solar cell according to claim 2, wherein the forming of the selective emitter solar cell base comprises forming a sub-buried grid electrode.

14. The method for fabricating a selective emitter solar cell according to claim 13, wherein the sub-buried grid electrode and the buried grid electrode intersect perpendicularly in the same plane, and the sub-buried grid electrode lies right underneath the bus-bar and in parallel to the bus-bar.

15. The method for fabricating a selective emitter solar cell according to claim 13, wherein the solar cell base is co-fired so that the bus-bar is connected with the buried grid electrode in the traversing direction underneath through the anti-reflection layer.

16. A selective emitter solar cell, comprising:
a selective emitter solar cell base having a buried grid electrode;
an anti-reflection layer formed on the emitter surface of the solar cell base; and
a bus-bar formed on the anti-reflection layer, which is connected with the buried grid electrode in the traversing direction underneath through the anti-reflection layer.

17. The selective emitter solar cell according to claim 16, wherein the selective emitter solar cell base having a buried grid electrode comprises:
a semiconductor substrate;
an emitter groove formed in the semiconductor substrate;
an emitter P-N junction formed near the emitter groove in the semiconductor substrate; and
a barrier layer, a conducting layer and a bond layer formed sequentially in the emitter groove.

18. The selective emitter solar cell according to claim 17, wherein the emitter groove has a width of 10˜50 μm and a depth of 10˜50 μm.

19. The selective emitter solar cell according to claim 16, wherein the bus-bar has a width of 3000˜5000 μm.

20. The selective emitter solar cell according to claim 17, wherein the semiconductor substrate surface has a sheet resistance larger than 100 Ω/□.

21. The selective emitter solar cell according to claim 17, wherein the emitter groove surface has a sheet resistance less than 30 Ω/□.

22. The selective emitter solar cell according to claim 17, wherein the material of the barrier layer is nickel, the material of the conducting layer is copper, and the material of the bond layer is silver.

23. The selective emitter solar cell according to claim 17, wherein the barrier layer has a thickness of 2˜20 μm, the conducting layer has a thickness of 5˜50 μm, the bond layer has a thickness of 5˜50 μm.

24. The selective emitter solar cell according to claim 16, wherein the material of the bus-bar is silver.

25. The selective emitter solar cell according to claim 16, wherein the bus-bar and the buried grid electrode are arranged perpendicularly to each other.

26. The selective emitter solar cell according to claim 25, wherein the buried grid electrodes are arranged in parallel to each other with the same distance therebetween.

27. The selective emitter solar cell according to claim 25, wherein the bus-bars are arranged in parallel to each other with the same distance therebetween.

28. The selective emitter solar cell according to claim 17, wherein a sub-buried grid electrode is formed in forming of the selective emitter solar cell base.

29. The selective emitter solar cell according to claim 28, wherein the sub-buried grid electrode and the buried grid electrode intersect perpendicularly in the same plane, and the sub-buried grid electrode lies right underneath the bus-bar and in parallel to the bus-bar.
